(19) United States
(12) Patent Application Publication
(10) Pub. No.: US 2019/0287772 A1
(43) Pub. Date: Sep. 19, 2019

(54) METHOD AND APPARATUS OF FORMING STRUCTURES BY SYMMETRIC SELECTIVE PHYSICAL VAPOR DEPOSITION

(71) Applicant: APPLIED MATERIALS, INC., Santa Clara, CA (US)

(72) Inventors: JOUNG JOO LEE, SAN JOSE, CA (US); Bencherki Mebarki, SANTA CLARA, CA (US); Xianmin Tang, SAN JOSE, CA (US); KEITH MILLER, MOUNTAIN VIEW, CA (US); SREE RANGASAI KESAPRAGADA, UNION CITY, CA (US); Sudarsan Srinivasan, SAN JOSE, CA (US)

(21) Appl. No.: 16/351,651

(22) Filed: Mar. 13, 2019

Related U.S. Application Data
(60) Provisional application No. 62/642,833, filed on Mar. 14, 2018.

(51) Int. Cl. H01J 37/34; C23C 14/54; H01L 21/02

(52) U.S. Cl. CPC H01J 37/3447; C23C 14/54; H01J 2237/3341; H01L 21/02266; H01L 21/02636

(57) ABSTRACT

Methods and apparatus for physical vapor deposition (PVD) are provided herein. In some embodiments, a method for PVD includes providing a first stream of a first material from a first PVD source towards a surface of a substrate at a first non-perpendicular angle to the plane of the substrate surface and rotating and linearly scanning the substrate through the stream of first material to deposit the first material on all features formed on the substrate, providing a second stream of an ionized dopant species from a dopant source towards the surface of the substrate at a second non-perpendicular angle to the plane of the substrate surface, and implanting the ionized dopant species in the first material deposited only on a top portion and a portion of the first and second sidewalls of all the features on the substrate by rotating and linearly scanning the substrate via the substrate support.

### CROSS-REFERENCE

This application claims benefit of U.S. provisional patent application Ser. No. 62/642,833, filed Mar. 14, 2018 which is herein incorporated by reference in its entirety.

### FIELD

Embodiments of the present disclosure generally relate to substrate processing equipment, and more particularly, to methods and apparatus for depositing materials via physical vapor deposition.

### BACKGROUND

The semiconductor processing industry generally continues to strive for increased uniformity of layers deposited on substrates. For example, with shrinking circuit sizes leading to higher integration of circuits per unit area of the substrate, increased uniformity is generally seen as desired, or required in some applications, in order to maintain satisfactory yields and reduce the cost of fabrication. Various technologies have been developed to deposit layers on substrates in a cost-effective and uniform manner, such as chemical vapor deposition (CVD) or physical vapor deposition (PVD).

However, the inventor has observed that with the drive to produce equipment to deposit more uniformly, certain applications may not be adequately served where purposeful deposition is required that is not symmetric or uniform with respect to the given structures being fabricated on a substrate.

Accordingly, the inventor has provided improved methods and apparatus for depositing materials via physical vapor deposition.

### SUMMARY

Methods and apparatus for physical vapor deposition (PVD) are provided herein. In some embodiments, a method for physical vapor deposition (PVD) includes providing a first stream of a first material from a first PVD source towards a surface of a substrate at a first non-perpendicular angle to the plane of the substrate surface to depositing the first material only on a top portion and a first sidewall of at least one feature formed on the substrate surface, rotating and linearly scanning the substrate through the stream of first material via the substrate support to deposit the first material on all features formed on the substrate, providing a second stream of an ionized dopant species from a dopant source towards the surface of the substrate at a second non-perpendicular angle to the plane of the substrate surface, directing the second stream of the ionized dopant species through at least one opening of the collimator to limit an angular range of the ionized dopant species passing through the opening; and implanting the ionized dopant species in the first material deposited only on a top portion and a portion of the first and second sidewalls of all the features on the substrate by rotating and linearly scanning the substrate via the substrate support.

In some embodiments, a method for forming structures by asymmetric selective physical vapor deposition (PVD) may include providing a first stream of a first material from a first PVD source towards a surface of a substrate at a first non-perpendicular angle to the substrate surface to depositing the first material only on a top portion and a first sidewall of at least one feature formed on the substrate surface; rotating a substrate support on which the substrate is retained to deposit the first material on a second sidewall of the at least one feature; linearly scanning the substrate through the stream of first material via the substrate support to deposit the first material on all features formed on the substrate; providing a second stream of an etch species from a plasma etch source towards the surface of the substrate at a second non-perpendicular angle to the substrate surface; directing the second stream of the etch species through at least one opening of a collimator to limit an angular range of the etch species passing through the opening; and using the etch species, selectively etching the first material deposited only on a top portion and a portion of the first and second sidewalls of all the features on the substrate by rotating and linearly scanning the substrate via the substrate support.

In some embodiments, an apparatus for forming structures by asymmetric selective physical vapor deposition (PVD) may include a substrate support configured to support a substrate when disposed thereon, and configured to rotate and move linearly, a first PVD source configured to provide a stream of a first material from towards a surface of a substrate at a first non-perpendicular angle to the substrate surface, wherein the first PVD source is configured to rotate to adjust the angle at which the stream of first material contacts the substrate surface; and a collimator having at least one opening to limit an angular range of first material passing through the at least one opening, wherein the collimator is configured to move linearly to control the angle at which the stream of first material contacts the substrate surface.

Other and further embodiments of the present invention are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1A depicts a schematic diagram of an apparatus used for PVD deposition of material on substrates in accordance with some embodiments of the present disclosure.

FIG. 1B depicts a schematic diagram of another apparatus used for PVD deposition of material on substrates in accordance with some embodiments of the present disclosure.

FIG. 2 depicts a flow chart of a method for PVD deposition of material on substrates in accordance with some embodiments of the present disclosure.

FIG. 3 depicts a schematic side view of a substrate including features having a layer of material deposited thereon in accordance with at least some embodiments of the present disclosure.

FIG. 4 depicts a schematic diagram of an apparatus used for PVD deposition of material on substrates in accordance with some embodiments of the present disclosure.

FIG. 5 depicts a flow chart of a method for PVD deposition of material on substrates in accordance with some embodiments of the present disclosure.

FIG. 6 depicts a schematic side view of a substrate including features having a layer of material deposited thereon in accordance with at least some embodiments of the present disclosure.

[owls] FIG. 7 depicts a schematic diagram of an apparatus used for PVD deposition of material on substrates in accordance with some embodiments of the present disclosure.

FIG. 8 depicts a flow chart of a method for PVD deposition of material on substrates in accordance with some embodiments of the present disclosure.

FIG. 9 depicts a schematic side view of a substrate including features having a layer of material deposited thereon in accordance with at least some embodiments of the present disclosure.

FIG. 10 depicts a flow chart of a method for PVD deposition of material on substrates in accordance with some embodiments of the present disclosure.

FIG. 11 depicts a schematic side view of a substrate including features having a layer of material deposited thereon in accordance with at least some embodiments of the present disclosure.

FIG. 12 depicts schematic top and side views of an apparatus for physical vapor deposition illustrating material deposition angles in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and apparatus for physical vapor deposition (PVD) are provided herein. Embodiments of the disclosed methods and apparatus advantageously enable uniform angular deposition of materials on a substrate. In such applications, deposited materials are asymmetric or angular with respect to a given feature on a substrate, but can be relatively uniform within all features across the substrate. Embodiments of the disclosed methods and apparatus advantageously enable new applications or opportunities for selective PVD of materials, thus further enabling new markets and capabilities. Furthermore, embodiments of the disclosed methods and apparatus advantageously can be used for fin selective doping and oxidation, selective spacer for a silicon fin, selective sidewall contact (e.g. Ti on Si), asymmetric deposition for tighter end-to-end spacing without extreme ultraviolet (EUV) lithography masks, asymmetric fin stressor for channel mobility, selective etch hard masks, Si fin protection layer, selective barrier deposition for low via R metallization with overhang control, spacer deposition for SAXP, line edge roughness control for etch hard mask, pattern CD, and profile modulation.

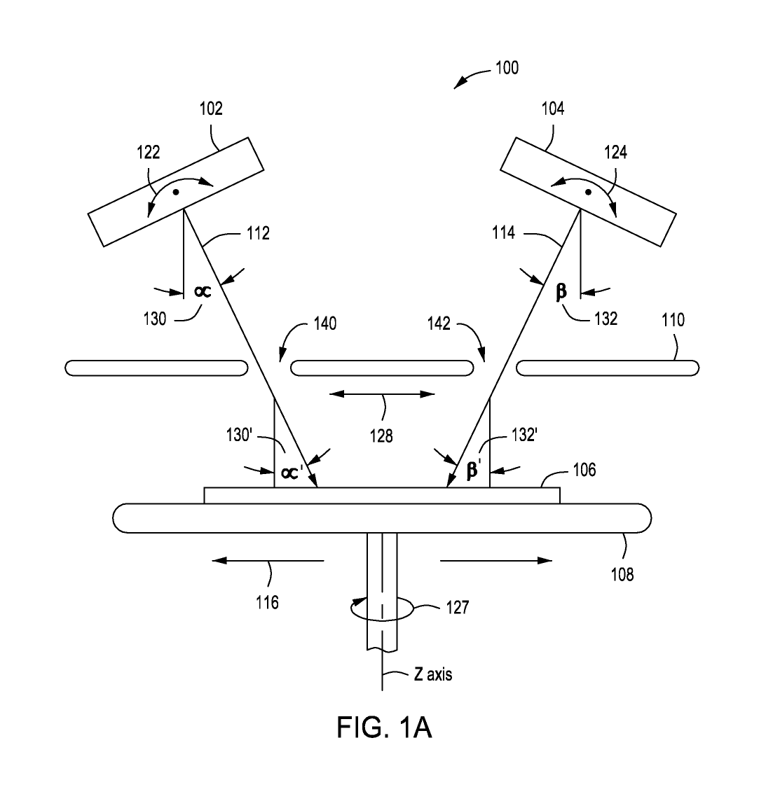

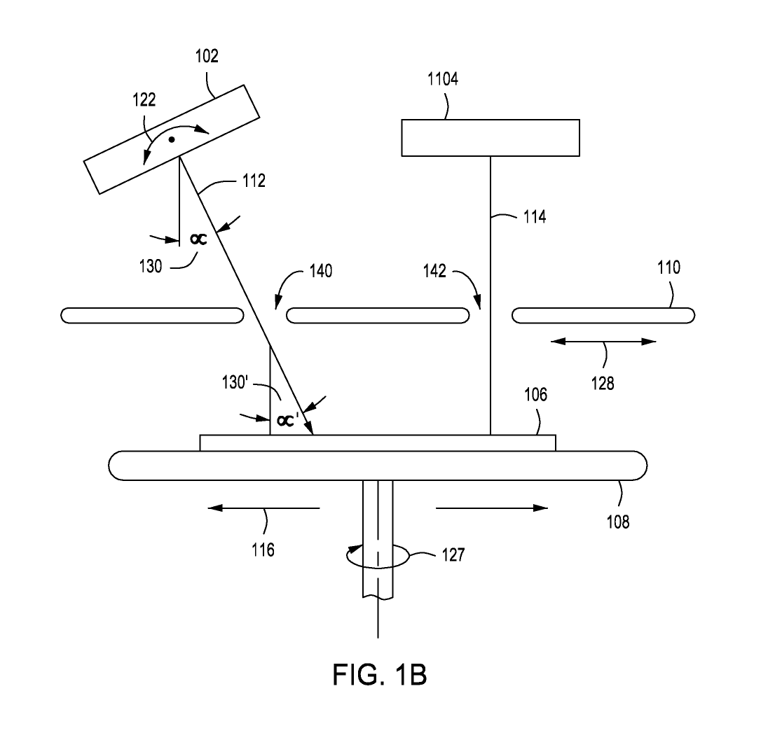

FIG. 1A is a schematic side view of an apparatus 100 for PVD in accordance with at least some embodiments of the present disclosure. Specifically, FIG. 1A schematically depicts an apparatus 100 for PVD of materials on a substrate at an angle to the generally planar surface of the substrate. The apparatus 100 generally includes a first PVD source 102, a substrate support 108 for supporting a substrate 106, and at least one collimator 110. The first PVD source 102 is configured to provide a first directed stream of material flux (stream 112 as depicted in FIG. 1A) from the source toward the substrate support 108 (and any substrate 106 disposed on the substrate support 108). In some embodiments, the apparatus 100 includes a second source 104 used in forming structures on the substrate. In some embodiments, the second source 104 can be one of a dopant source, an annealing source used for annealing, or a directed etch plasma source, each of which is configured to provide a second directed stream of dopant, annealing light/heat, or etch species, respectively (stream 114 as depicted in FIG. 1A) from the source 104 toward the substrate support 108 (and any substrate 106 disposed on the substrate support 108). The substrate support has a support surface to support the substrate such that a working surface of the substrate to be deposited on is exposed to the first stream 112 of material flux and the second stream 114. In some embodiments, the first stream 112 of material flux provided by the first PVD source 102 has a width greater than that of the substrate support 108 (and any substrate 106 disposed on the substrate support 108). The stream 112 of material flux has a linear elongate axis corresponding to the width of the stream 112 of material flux. The substrate support 108 is configured to move linearly with respect to the first PVD source 102 and the second source 104, as indicated by arrows 116. In some embodiments, the substrate support 108 is additionally configured to rotate about its z-axis as indicated by arrow 127.

The first PVD source 102 includes target material to be sputter deposited on the substrate. In some embodiments, the target material can be, for example, a metal, such as titanium, or the like, suitable for depositing titanium (Ti) or titanium nitride (TiN) on the substrate. In some embodiments, the target material can be, for example, silicon, or a silicon-containing compound, suitable for depositing silicon (Si), silicon nitride (SiN), silicon oxynitride (SiON), or the like on the substrate. Other materials may suitably be used as well in accordance with the teachings provided herein. The linear PVD source 102 further includes, or is coupled to, a power source to provide suitable power for forming a plasma proximate the target material and for sputtering atoms off of the target material. The power source can be either or both of a DC or an RF power source.

In some embodiments, unlike an ion beam or other ion source, the first PVD sources 102 is configured to provide mostly neutrals and few ions of the target material. As such, a plasma may be formed having a sufficiently low density to avoid ionizing too many of the sputtered atoms of target material. For example, for a 300 mm diameter wafer as the substrate, about 1 to about 20 kW of DC or RF power may be provided. The power or power density applied can be scaled for other size substrates. In addition, other parameters may be controlled to assist in providing mostly neutrals in the stream 112 of material flux. For example, the pressure may be controlled to be sufficiently low so that the mean free path is longer than the general dimensions of an opening of the first PVD source 102 through which the stream of material flux passes toward the substrate support 108 (as discussed in more detail below). In some embodiments, the pressure may be controlled to be about 0.5 to about 5 millitorr.

In embodiments consistent with the present disclosure, the angles of incidence of the first and second streams 112, 114 can be controlled. For example, FIG. 1A depicts apparatus 100 illustrating material deposition angle α 130 of the first stream 112 from the first PVD source 102 and angle β 132 of the second stream 114 from the second source 104 in accordance with at least some embodiments of the present disclosure. In some embodiments, the angles α 130 and β 132 can either be fixed or adjustable by rotating the first PVD source 102 as shown by arrow 122, and/or rotating the second source 104 as shown by arrow 124.

As discussed above the apparatus includes at least one collimator 110. In some embodiments, the collimator 110 is a physical structure such as a shroud, disk, or a plurality of baffles that have one or more openings 140, 142 that is interposed between the sources 102, 104 and the substrate 106 such that the streams 112, 114 travel through the structure (e.g., collimator 110). Any materials, light, heat, etc. with an angle to great to pass through the openings 140, 142 of the collimator 110 will be blocked, thus limiting the permitted angular range of materials, light, heat, etc. reaching the surface of substrate 106. In some embodiments, the collimator 110 may include a single opening. In other embodiments, the apparatus 100 may include a single collimator 110 having multiple openings. Still, in other embodiments, the collimator may be comprised of multiple collimators, each having one or more openings. As used herein, the collimator functions as a spread angle control apparatus that controls the angle of the spread of materials, light, heat, etc. being provided by the first and/or second sources. In some embodiments, the one or more collimators 110 can move linearly as shown by arrow 128.

In some embodiments, the angle of incidence 130′, 132′ at which the streams 112, 114 actually contact the substrate surface may be different than the angle of incidence 130, 132 at which the streams of material are provide by the first PVD source 102 and the second source 104. The angle of incidence 130′, 132′ at which the streams 112, 114 actually contact the substrate surface can be independently controlled/altered by one or more of the following: the angle of incidences 130 and/or 132 at which the streams are provided by the first PVD source 102 and the second source 104, the number and placement of openings in collimator 110, the linear position of collimator 110, and the rotation 126 of the substrate support about the y-axis.

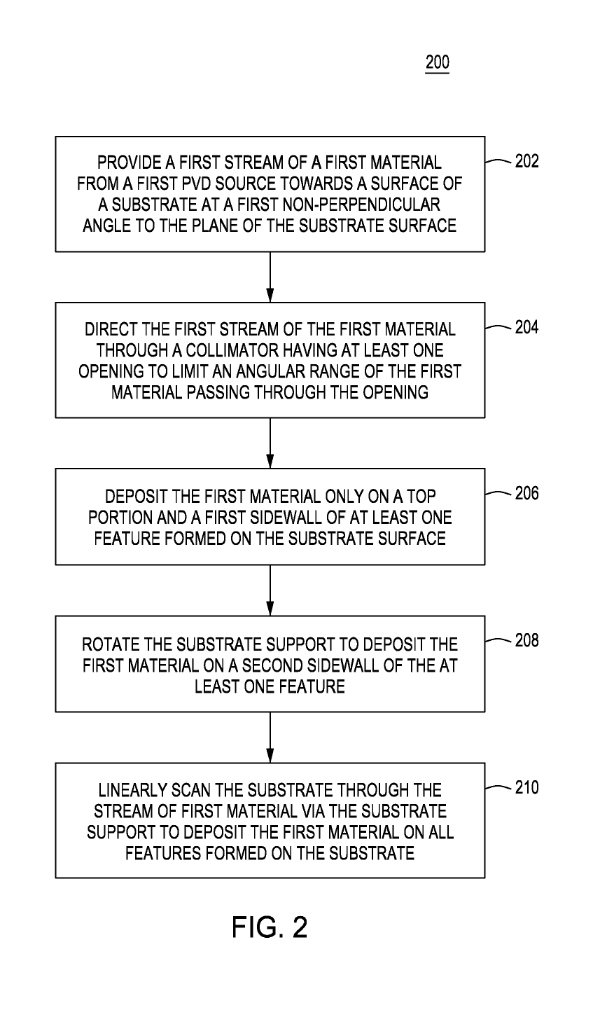

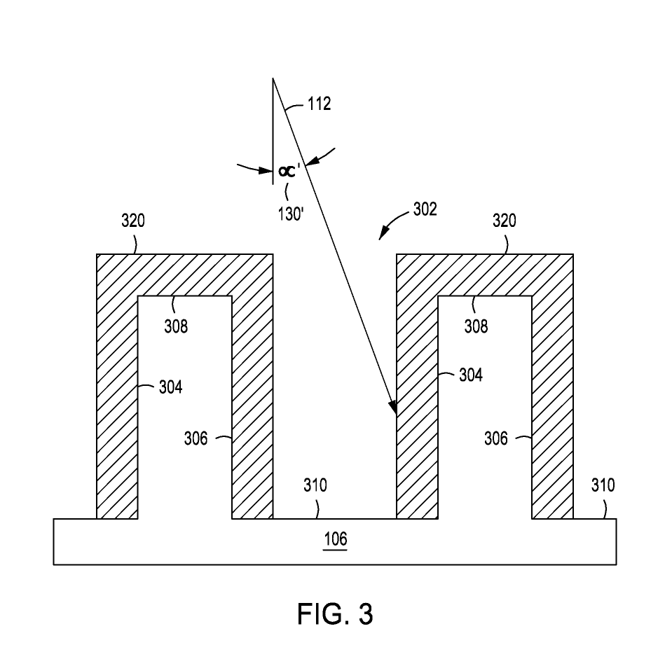

The methods and embodiments disclosed herein advantageously enable deposition of materials with a shaped profile with respect to a given feature on a substrate while maintaining overall deposition and shape uniformity across all features on a substrate. In addition, the methods and embodiments disclosed herein advantageously use at least one of a dopant source, an annealing light/heat source used for annealing, or a plasma etching source to further process the materials from the PVD source deposited on the features of the substrate. In each of the methods that perform additional processing such as doping, annealing, etching, etc., the first layer of material from the PVD source must be deposited on the features of the substrate. FIG. 2 depicts a flow diagram of a method 200 for depositing this first layer of target material 320 on features 302 formed on the substrate surface 106 as shown in FIG. 3. Specifically, FIG. 3 depicts a schematic side view of a substrate 106 including features 302 having a layer of material 320 deposited thereon in accordance with at least some embodiments of the present disclosure. The feature 302 can be a fin, trench, a via, or dual damascene feature, or the like. In addition, the feature 302 can protrude from the substrate rather than extend into the substrate. Each feature 302 includes a top portion 308, a first sidewall 304, a second sidewall 306, and a bottom portion 310.

The method 200 for depositing target material 320 on features 302 formed on the substrate surface 106 as shown in FIG. 3, begins at 202 where a first stream of a first material 112 is provided from a first PVD source 102 towards a surface of a substrate 106 at a first non-perpendicular angle to the plane of the substrate surface.

At 204, the first stream 112 of the first material is directed through a first collimator 110 having at least one opening 140 to limit the angular range of the first material passing through the at least one opening 140 of the collimator 110. In some embodiments, it is the combination of (1) the angle 130 of the stream 112 provided by the first PVD source 204 and (2) the physical structure and placement (i.e., linearly movement and height) of the collimator 110 that controls the angle of incidence 130′ that the stream of first material contacts the surface of the substrate. By controlling the angle of incidence 130′, asymmetric deposition of the target material onto the features can be accomplished. Specifically, at 206 the first material 320 is deposited only on the top portion 308 and a first side wall 304 of at least one feature formed on the substrate surface. At this point, there is little or no deposition on the second sidewall 306 and no deposition on the bottom portion 310 of feature 302 except in the corner where the bottom portion meets the first sidewall 304. In some embodiments, there is no material deposition on the bottom portion 310 at all. Also, as shown in FIG. 3, the deposition of material 320 on the first sidewall 304 extends from the top portion 308 to the bottom portion 310 of feature 302.

Then, at 208, the substrate is rotated by rotating the substrate support 108 on which the substrates is retained about its z-axis as shown by arrow 127. By rotating the substrate, the first material 320 can be deposited on the second wall 306. Again, there is little or no deposition on the bottom portion 310 of feature 302 except in the corner where the bottom portion meets the first sidewall 304 and the second sidewall 306. In some embodiments, there is no material deposition on the bottom portion 310 at all. Also, as shown in FIG. 3, the deposition of material 320 on the first sidewall 304 and the second sidewall 306 extends from the top portion 308 to the bottom portion 310 of feature 302.

At 210, the substrate is moved linearly (i.e., radially inward and outward) via the substrate support (i.e., linearly scanned) through the stream of first material to deposit the first material on all features formed on the substrate as shown in FIG. 3.

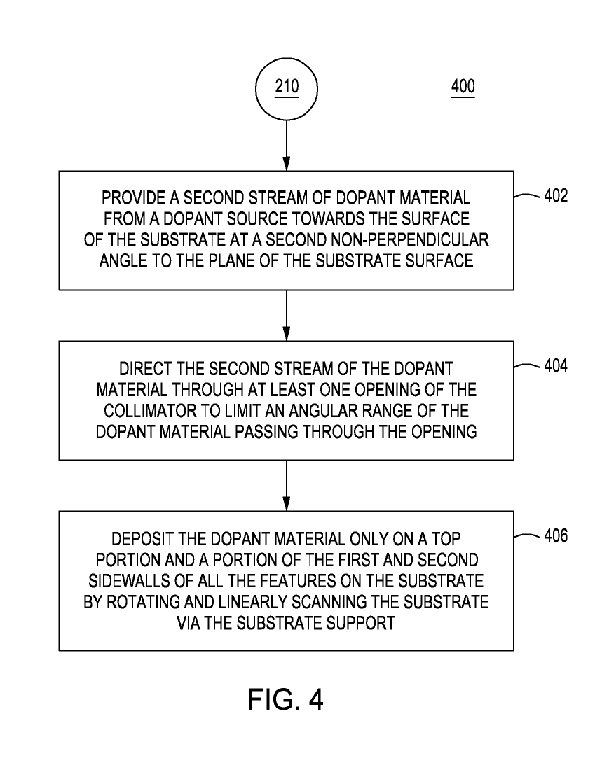

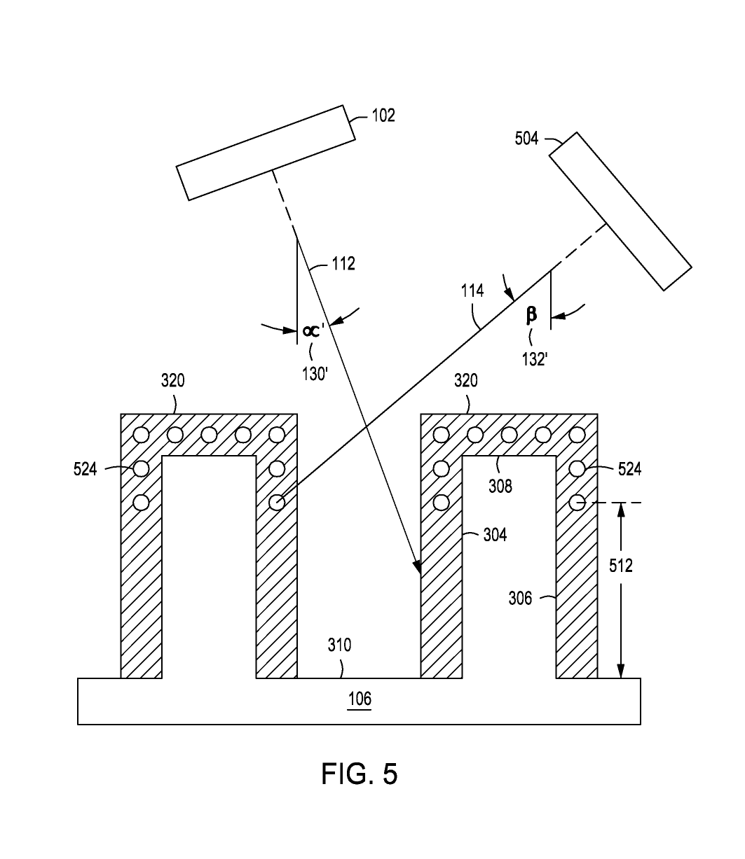

FIG. 4 depicts a flow diagram of a method 400 for implanting target material 320 with an ionized dopant species 524 on features 302 formed on the substrate surface 106 as shown in FIG. 5. Specifically, FIG. 5 depicts a schematic side view of a substrate 106 including features 302 having a layer of target material 320 as previously described with respect to FIGS. 2 and 3 deposited thereon, along with an ionized dopant species 524 implanted within a portion of the first material 320 (i.e., selective doping).

The method 400 for selectively implanting the ionized dopant species 524 within a selected portion of the first material 320 as shown in FIG. 5, continues from 210 for FIG. 2 and begins at 402 where a second stream 114 of materials comprised of an ionized dopant species 524 from a dopant source 504 is directed towards the surface of the substrate at a second non-perpendicular angle 132 to the plane of the substrate surface.

The dopant source 504 is a schematic representation of the structure used to perform ion implantation as generally known in the art. For example, a plasma may be formed by dopant source 504 from a dopant-containing gas, such as one or more of phosphine (PH₃), borane (BH₃), or other dopant-containing gases. Dopants may include, for example, one or more of nitrogen (N), phosphorus (P), boron (B), carbon (C), or arsenic (As). The plasma may include the ionized dopant species 524 which may be directed by a bias voltage towards the substrate surface and implanted therein. For example, one or more of the plasma density and or the bias voltage may be controlled, for example, to prevent unwanted penetration of the ionized dopant species within the first material 320. For example, in some embodiments, the plasma density may range from about 5×10⁹ to about 1×10¹¹ ions/cm³. For example, in some embodiments, the bias voltage may range from about 100 to about 500 V. In some embodiments, the ion implantation may extend to a depth ranging from about 0 to about 30 angstroms. In some embodiments, the ion implantation does not extend completely through the first material 320 having the surface being modified. In some embodiments, the concentration of dopants implanted in the first material 320 may range from about 5×10¹⁹ to about 5×10²¹ atoms/cm³.

At 404, the second stream 114 comprised of the ionized dopant species 524 is directed through a first collimator having at least one opening to limit the angular range of the second stream 114 of the ionized dopant species 524 passing through at least one opening of the collimator 110. In some embodiments, it is the combination of (1) the angle of the second stream 114 provided by the second source 104, in this case dopant source 504, (2) the physical structure and placement (i.e., linearly movement and height) of the collimator(s), and/or (3) the bias voltage used to direct the ionized dopant species that controls the angle of incidence 132′ that the stream 114 of the ionized dopant species contacts the surface of the substrate. By controlling the angle of incidence 132′ of the second stream 114 of ionized dopant species 524, the desired implantation of the ionized dopant species 524 within the desired portion of the target material 320 deposited on features 302 can be accomplished.

At 406, the substrate is rotated and moved linearly via the substrate support (i.e., radially scanned) through the stream 114 of the ionized dopant species 524 to implant the ionized dopant species 524 within a portion of the first material 320 (i.e., selective doping) only on (1) a top portion and (2) a portion of both a first sidewall and a second sidewall of all features formed on the substrate, as shown in FIG. 5. In this way, the height 512 from the bottom portion 310 to the portion of the first material 320 implanted with the dopant species 524 on sidewalls 304 and 306 can be precisely controlled.

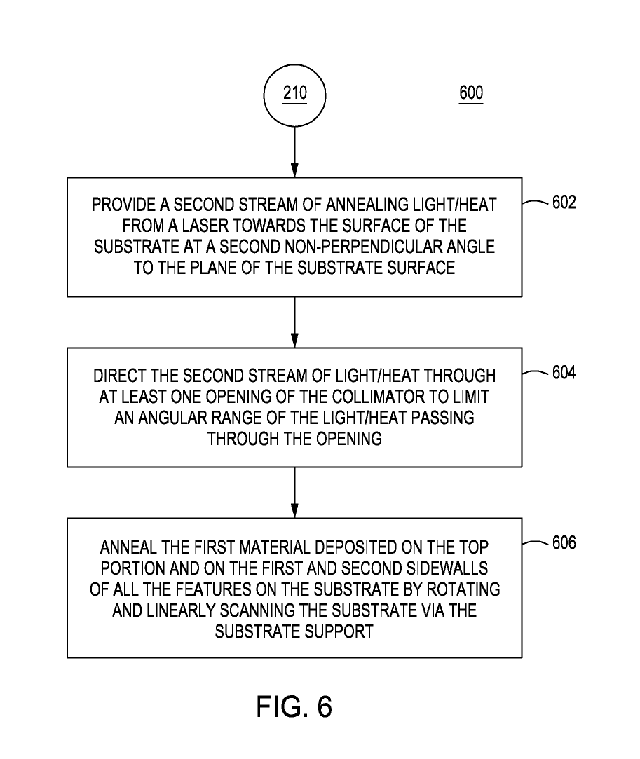

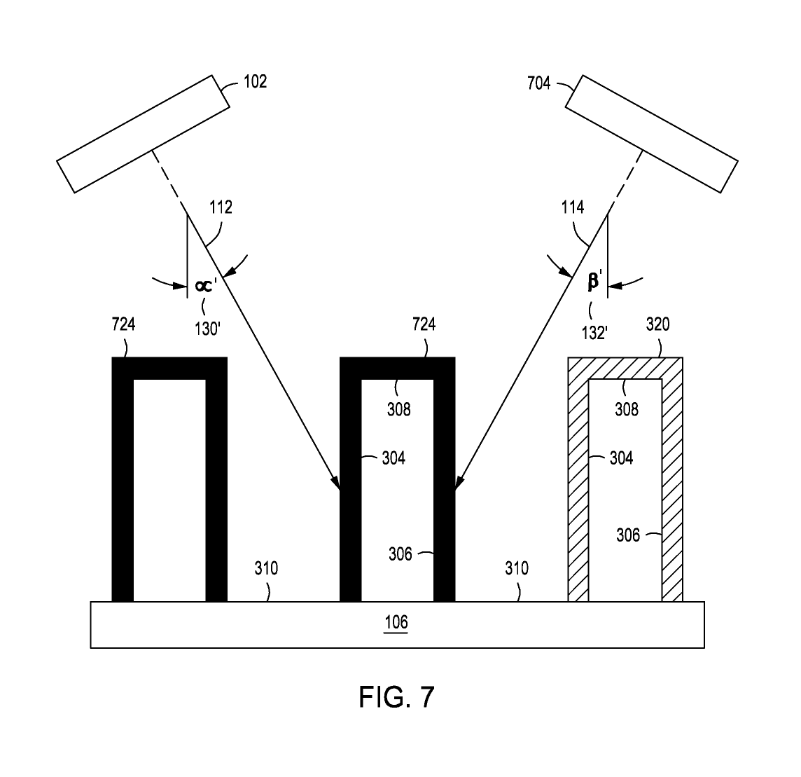

FIG. 6 depicts a flow diagram of a method 600 for annealing target material 320, using a directed annealing light/heat source on features 302, formed on the substrate surface 106 as shown in FIG. 7. Specifically, FIG. 7 depicts a schematic side view of a substrate 106 including features 302 having a layer of target material 320 as previously described with respect to FIGS. 2 and 3 deposited thereon, that has been uniformly annealed.

The method 600 for selectively annealing a selected portion of the first material 320 as shown in FIG. 5, continues from 210 for FIG. 2 and begins at 602 where a second stream 114 of light/heat from an annealing source 704 is directed towards the surface of the substrate at a second non-perpendicular angle 132 to the plane of the substrate surface.

The annealing source 704 is a schematic representation of the structure used to perform the annealing process as generally known in the art. For example, the annealing source 704 may one or more of a LASER, LED light source, conventional lamps (e.g., tungsten-halogen, mercury vapor, arc discharge), or electrical heating elements. In some embodiments, the annealing process may be performed by exposing the first material 320 to the second stream 114 of light/heat to heat it to a temperature of about 800 to about 1200 degrees Celsius for a desired period of time, such as about 0.1 seconds to about 30 minutes. In some embodiments, the anneal process may be performed in a hydrogen environment or an inert atmosphere, such as an atmosphere including nitrogen (N₂), argon (Ar), or the like. In some embodiments, the annealing process described in FIGS. 6 and 7 may be used to activate the dopants implanted in the first material described with respect to FIGS. 4 and 5.

At 604, the second stream 114 of annealing light/heat 724 is directed through a first collimator having at least one opening to limit the angular range of the second stream 114 of annealing light/heat 724 passing through at least one opening of the collimator 110. In some embodiments, it is the combination of (1) the angle of the second stream 114 provided by the second source 104, in this case annealing source 704, and/or (2) the physical structure and placement (i.e., linearly movement and height) of the collimator(s) that controls the angle of incidence 132′ that the stream 114 of annealing light/heat 724 contacts the surface of the substrate. By controlling the angle of incidence 132′ of the second stream 114 of annealing light/heat 724, the amount of annealing of the desired portion of the target material 320 deposited on features 302 can be accomplished.

At 606, the substrate is rotated and moved linearly via the substrate support (i.e., radially scanned) through the stream 114 of the annealing light/heat 724 to selectively anneal the desired portion of the first material 320 (i.e., selective annealing).

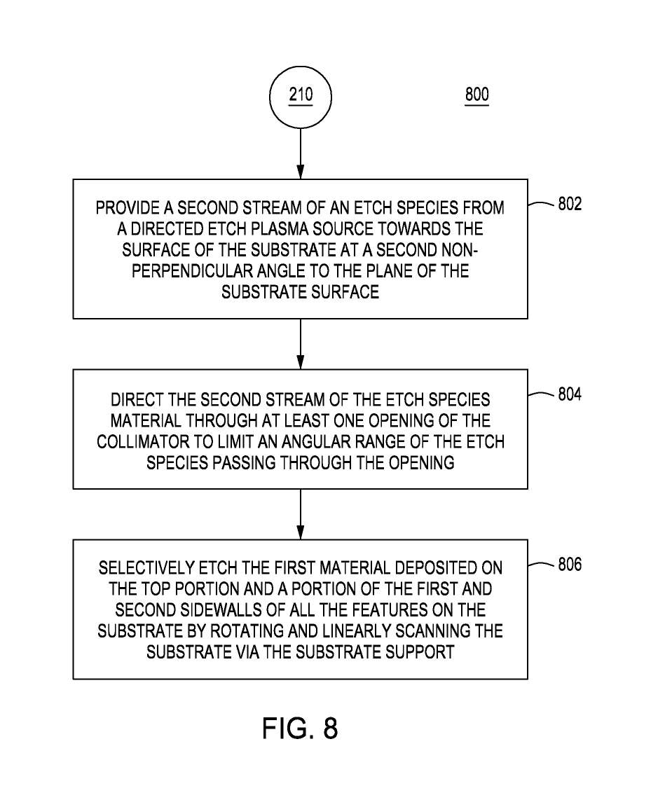

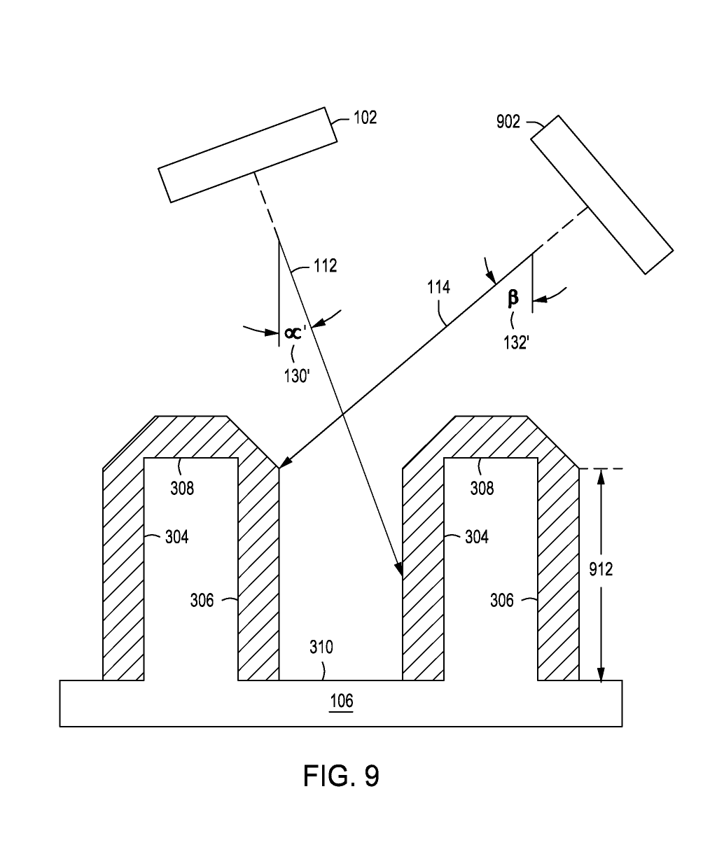

FIG. 8 depicts a flow diagram of a method 800 for etching a portion of target material 320 using a directed stream 114 of a plasma etch species 924 on features 302 formed on the substrate surface 106 as shown in FIG. 9. Specifically, FIG. 9 depicts a schematic side view of a substrate 106 including features 302 having a layer of target material 320 as previously described with respect to FIGS. 2 and 3 deposited thereon, along with selected portions of the target material 320 etched off using a plasma etch species 924 (i.e., selective etching).

The method 800 for selectively etching selected portions of the target material 320 as shown in FIG. 9, continues from 210 for FIG. 2 and begins at 802 where a second stream 114 of etch material (i.e., etch species 924) from a plasma etch source 904 is directed towards the surface of the substrate at a second non-perpendicular angle 132 to the plane of the substrate surface.

The directed plasma etch source 904 is a schematic representation of the structure used to perform the etch process as generally known in the art. For example, a plasma may be formed, by etch source 904, from a process gas comprising hydrogen (H₂) gas. In some embodiments, the plasma is formed from a process gas consisting of, or consisting essentially of, hydrogen (H₂) gas. In some embodiments, the process gas further comprises one or more noble gases, such as argon (Ar), helium (He), krypton (Kr), neon (Ne), xenon (Xe), or the like. In some embodiments, the process gas consists of, or consists essentially of, hydrogen (H₂) gas and one or more noble gases. Other etch species may be used depending on the first material 320 being etched.

At 804, the second stream 114 comprised of the plasma etch species 924 is directed through a first collimator having at least one opening to limit the angular range of the second stream 114 of the etch species 924 passing through at least one opening of the collimator 110. In some embodiments, it is the combination of (1) the angle of the second stream 114 provided by the second source 104, in this case etch source 904, (2) the physical structure and placement (i.e., linearly movement and height) of the collimator(s), and/or (3) a bias voltage used to direct the etch species 924 that controls the angle of incidence 132′ that the stream 114 of the etch species 924 contacts the surface of the substrate. By controlling the angle of incidence 132′ of the second stream 114 of the etch species 924, the desired implantation of the etch species 924 within the desired portion of the target material 320 deposited on features 302 can be accomplished.

At 806, the substrate is rotated and moved linearly via the substrate support (i.e., radially scanned) through the stream 114 of the etch species 924 to etch a portion of the first material 320 (i.e., selective etching), as shown in FIG. 9. In this way, the height 912 from the bottom portion 310 to the portion of the first material 320 being etched on the top 308 and on sidewalls 304 and 306 can be precisely controlled.

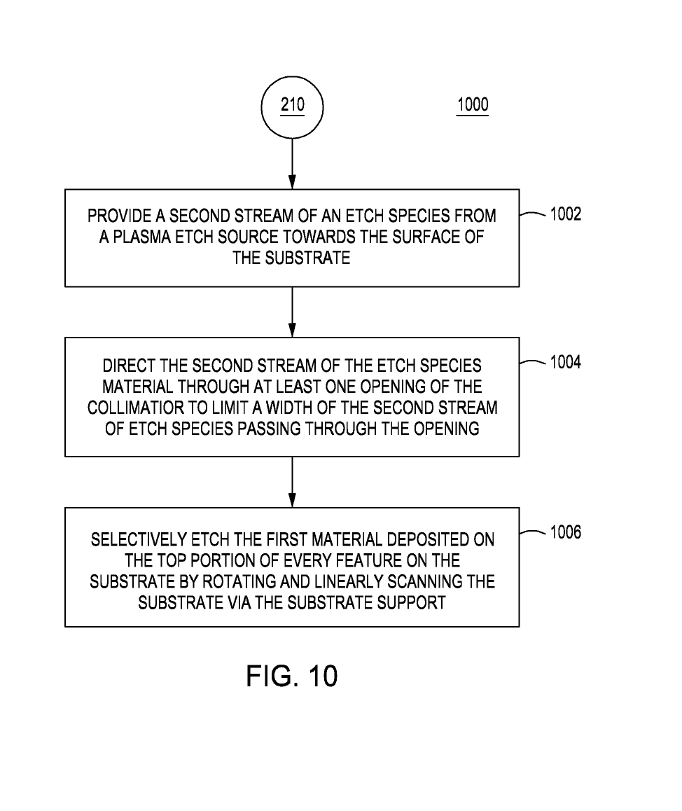

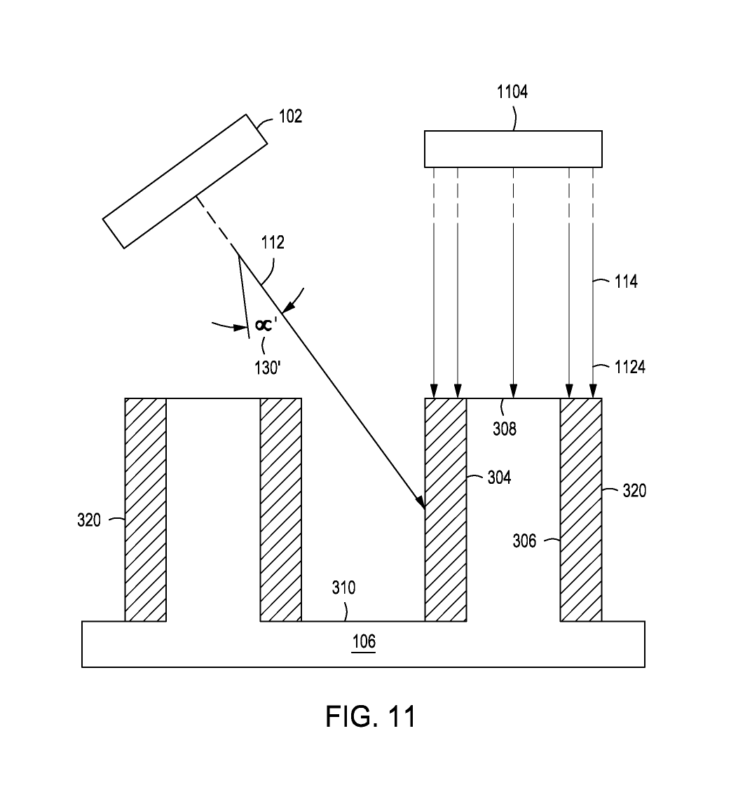

FIG. 10 depicts a flow diagram of a method 1000 for etching a top portion of target material 320 using a stream 114 of a plasma etch species 924 supplied perpendicular to the substrate surface on features 302 formed on the substrate surface 106 as shown in FIGS. 1B and 11. FIG. 1B is the same as FIG. 1A except that the second source 1104 provides the second stream 114 perpendicular to the substrate support surface unlike the second source 104 in FIG. 1A. FIG. 11 depicts a schematic side view of a substrate 106 including features 302 having a layer of target material 320 as previously described with respect to FIGS. 2 and 3 deposited thereon, along with selected top portions of the target material 320 etched off using a plasma etch species 1124 (i.e., selective etching).

The method 1000 for selectively etching selected portions of the target material 320 as shown in FIG. 11, continues from 210 for FIG. 2 and begins at 1002 where a second stream 114 of etch material (i.e., etch species 1124) from a plasma etch source 1104 is directed towards the surface of the substrate perpendicular to the plane of the substrate surface.

The plasma etch source 1104 is a schematic representation of the structure used to perform the etch process as generally known in the art. For example, a plasma may be formed, by etch source 1104, from a process gas comprising hydrogen (H₂) gas. In some embodiments, the plasma is formed from a process gas consisting of, or consisting essentially of, hydrogen (H₂) gas. In some embodiments, the process gas further comprises one or more noble gases, such as argon (Ar), helium (He), krypton (Kr), neon (Ne), xenon (Xe), or the like. In some embodiments, the process gas consists of, or consists essentially of, hydrogen (H₂) gas and one or more noble gases. Other etch species may be used depending on the first material 320 being etched.

At 1004, the second stream 114 comprised of the plasma etch species 1124 is directed through a first collimator having at least one opening to limit a width of the second stream 114 of the etch species 1124 passing through at least one opening of the collimator 110.

At 1006, the substrate is rotated and moved linearly via the substrate support (i.e., radially scanned) through the stream 114 of the etch species 1124 to etch just the top portion of the first material 320 (i.e., selective etching), as shown in FIG. 11.

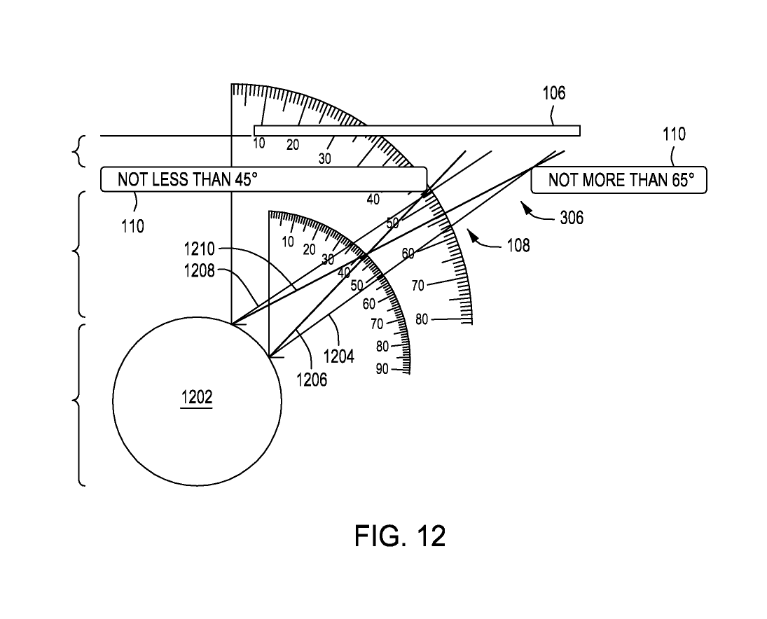

FIG. 12 is a schematic side view of a portion of an apparatus for physical vapor deposition illustrating material deposition angles in accordance with at least some embodiments of the present disclosure described above. As shown in FIG. 12, to control the size of the streams 112, 114, in addition to the angle of incidence, several parameters can be predetermined, selected, or controlled. For example, a diameter 1212 or width of a target 1202 can be predetermined, selected, or controlled. In addition, a first working distance 1214 from the target the collimator openings 140, 142 can be predetermined, selected, or controlled. A second working distance 1216 from the collimator openings 140, 142 to the substrate 106 can also be predetermined, selected, or controlled. Lastly, the size and number of the collimator openings 140, 142 can be predetermined, selected, or controlled. Taking these parameters into account, the minimum and maximum angles of incidence can be predetermined, selected, or controlled as shown in FIG. 12.

For example, with a given target diameter 1212 of target 1202, working distance 1214, and second working distance 1216, the size of the collimator openings 140, 142 can be set to control a width of the streams 112, 114 that passes through the opening an impinges upon the substrate 106. For example, the collimator openings 140, 142 can be set to control the minimum and maximum angles of incidence of material, light, heat, etc. from the streams 112, 114. For example, with respect to a PVD source, lines 1206 and 1204 represent possible paths of material from a first portion of the target 1202 that can pass through the collimator openings 140, 142. Lines 1208 and 1210 represent possible paths of material from a second portion of the target 1202 that can pass through the collimator openings 140, 142. The first and second portions of the target 1202 represent the maximum spread of materials with line of sight paths to the collimator openings 140, 142. The overlap of paths of materials that can travel via line of sight through the collimator openings 140, 142 are bounded by lines 1206 and 1210, which represent the minimum and maximum angles of incidence of material from the stream 112 of material flux that can pass through the opening and deposit on the substrate 106. The angles of 45 degrees and 65 degrees are illustrative. For example, the angle of impingement may generally range between about 10 to about 65 degrees, or more.

While the foregoing is directed to embodiments of the present disclosure, other and further embodiments of the disclosure may be devised without departing from the basic scope thereof.

1. A method for forming structures by asymmetric selective physical vapor deposition (PVD), comprising:
providing a first stream of a first material from a first PVD source towards a surface of a substrate at a first non-perpendicular angle to the substrate surface to depositing the first material only on a top portion and a first sidewall of at least one feature formed on the substrate surface;
directing the stream of the first material through a first collimator having at least one opening to limit an angular range of first material passing through the at least one opening;
rotating a substrate support on which the substrate is retained to deposit the first material on a second sidewall of the at least one feature; and
linearly scanning the substrate through the stream of first material via the substrate support to deposit the first material on all features formed on the substrate.

2. The method of claim 1, wherein the combination of (1) the angle of the stream of the first material through a first collimator provided by the first PVD source and (2) the physical structure and placement of the collimator controls an angle of incidence that the stream of first material contacts the surface of the substrate.

3. The method of claim 1, wherein the feature is one of a fin, trench, a via, dual damascene feature, or protrudes from the substrate rather than extend into the substrate.

4. The method of claim 1, wherein there is little or no material is deposited on a bottom portion of the feature except in a corner where the bottom portion meets the first sidewall.

5. The method of claim 1, wherein the collimator one of a shroud, a disk, or a plurality of baffles and has one or more openings formed through the collimator such that streams of material flux travels through the collimator.

6. The method of claim 1, wherein the collimator is comprised of a plurality of collimators, each having one or more openings.

7. The method of claim 1, further comprising:
providing a second stream of an ionized dopant species from a dopant source towards the surface of the substrate at a second non-perpendicular angle to the substrate surface;
directing the second stream of the ionized dopant species through at least one opening of a collimator to limit an angular range of the ionized dopant species passing through the at least one opening; and
implanting the ionized dopant species in the first material deposited only on a top portion and a portion of the first and second sidewalls of all the features on the substrate by rotating and linearly scanning the substrate via the substrate support.

8. The method of claim 7, wherein dopants in the ionized dopant species includes one or more of nitrogen (N), phosphorus (P), boron (B), carbon (C), or arsenic (As).

9. The method of claim 7, wherein, the ion implantation extends to a depth ranging from about 0 to about 30 angstroms.

10. The method of claim 1, further comprising:
providing a second stream of annealing light and/or heat from an annealing source is directed towards the surface of the substrate at a second non-perpendicular angle to the substrate surface;
directing the second stream of annealing light and/or heat through at least one opening of a collimator to limit an angular range of the annealing light and/or heat passing through the at least one opening; and
selectively annealing portions of the first material by rotating and linearly scanning the substrate via the substrate support.

11. The method of claim 10, wherein the annealing source is one or more of a LASER, LED light source, conventional lamps, or electrical heating elements.

12. The method of claim 10, wherein the annealing process is performed by exposing the first material to the second stream of annealing light and/or heat to heat the first material to a temperature of about 800 to about 1200 degrees Celsius for a predetermined period of time.

13. The method of claim 10, wherein the annealing process is performed in a hydrogen environment or an inert atmosphere.

14. Method for forming structures by symmetric selective physical vapor deposition (PVD), comprising:
providing a first stream of a first material from a first PVD source towards a surface of a substrate at a first non-perpendicular angle to the substrate surface to depositing the first material only on a top portion and a first sidewall of at least one feature formed on the substrate surface;
rotating a substrate support on which the substrate is retained to deposit the first material on a second sidewall of the at least one feature;
linearly scanning the substrate through the stream of first material via the substrate support to deposit the first material on all features formed on the substrate;
providing a second stream of an etch species from a plasma etch source towards the surface of the substrate at a second non-perpendicular angle to the substrate surface;
directing the second stream of the etch species through at least one opening of a collimator to limit an angular range of the etch species passing through the at least one opening; and
using the etch species, selectively etching the first material deposited only on a top portion and a portion of the first and second sidewalls of all the features on the substrate by rotating and linearly scanning the substrate via the substrate support.

15. The method of claim 14, wherein at least one of (1) the angle of the second stream of the etch species provided by the plasma etch source, (2) the physical structure and placement of the collimator, or (3) a bias voltage used to direct the etch species controls an angle of incidence that the second stream of the etch species contacts the surface of the substrate.

16. The method of claim 14, wherein the feature is one of a fin, trench, a via, dual damascene feature, or protrudes from the substrate rather than extend into the substrate.

17. The method of claim 14, wherein the collimator one of a shroud, a disk, or a plurality of baffles and has one or more openings formed through the collimator such that streams of material flux travels through the collimator.

18. The method of claim 14, wherein the collimator is comprised of a plurality of collimators, each having one or more openings.

19. Apparatus for forming structures by asymmetric selective physical vapor deposition (PVD), comprising:
a substrate support configured to support a substrate when disposed thereon, and configured to rotate and move linearly;
a first PVD source configured to provide a stream of a first material from towards a surface of the substrate at a first non-perpendicular angle to the substrate surface, wherein the first PVD source is configured to rotate to adjust the angle at which the stream of first material contacts the substrate surface; and
a collimator having at least one opening to limit an angular range of first material passing through the at least one opening, wherein the collimator is configured to move linearly to control the angle at which the stream of first material contacts the substrate surface.

20. The apparatus of claim 19, wherein the linear movement of the collimator is used to adjust an angle of incidence that the stream of first material contacts the substrate surface such that a height of the deposition of material on sidewalls from a bottom portion of the structure is precisely controlled.
